(19) United States
(12) Patent Application Publication
(10) Pub. No.: US 2006/0197581 A1
(43) Pub. Date: Sep. 7, 2006

(54) Temperature detecting circuit

(76) Inventors: Yong-Jin Chun, Hyogo (JP); Hirofumi Watanabe, Hyogo (JP)

Correspondence Address: COOPER & DUNHAM, LLP, 1185 AVENUE OF THE AMERICAS, NEW YORK, NY, 10036, US

(21) Appl. No.: 11/370,273

(22) Filed: Mar. 6, 2006

(30) Foreign Application Priority Data
Mar. 7, 2005 (JP) 2005-062433

(51) Int. Cl. H01L 35/00

(52) U.S. Cl. 327/512

(57) ABSTRACT

A high precision temperature detecting circuit is disclosed. The temperature detecting circuit includes a first voltage source circuit for generating a voltage VPN that has a negative temperature coefficient using a work function difference of gate electrodes of two field effect transistors,
a second voltage source circuit for generating a reference voltage VREF1 that is independent of temperature change using a work function difference of gate electrodes of two or more field effect transistors,
an impedance conversion circuit for converting impedance of the voltage VPN and the reference voltage VREF1, and
a subtracter circuit, to which the impedance converted voltages VPN and VREF1 are provided, for obtaining a difference voltage between the voltage VPN and the reference voltage VREF1, and for amplifying the difference voltage.

### BACKGROUND OF THE INVENTION

1. Field of the Invention

The present invention relates to a highly precise temperature detecting circuit that is capable of operating at a low battery voltage and with low power consumption.

2. Description of the Related Art

Conventionally, as a temperature detecting circuit, a voltage source (PTAT: Proportional-To-Absolute-Temperature) for providing a voltage proportional to an absolute temperature using a bipolar transistor is known. A voltage Vbe between a base and an emitter of the bipolar transistor decreases with a temperature rise with an approximately 2 mV/° C. negative temperature coefficient. The voltage Vbe between the base and emitter where a collector of the bipolar transistor is biased with a collector current i1 is expressed by the following formula:
Vbe=(kT/q)×ln(i1/is) (a)

where k represents the Boltzmann's constant, T represents the absolute temperature, and q represents the amount of charge of a carrier. Further, “is” represents a saturation current of the transistor and is greatly dependent on a process.

However, the influence of the process dependent “is” can be eliminated by using a difference of voltages between the base and the emitter of two bipolar transistors that are biased with different collector bias currents, i1 and i2, as shown by the following formula (b).
Vptat=Vbe(i2)−Vbe(i1)=(kT/q)×ln(i2/is)−(kT/q)×ln(i1/is)=(kT/q)×ln(i2/i1) (b)

As shown by the formula (b), since the voltage Vptat output from the PTAT circuit is determined only by temperature and a current ratio, except for the constants, a source voltage that is proportional to absolute temperature is realized independent of the process.

Conventionally, the PTAT circuit used to require a supply voltage of 12 V and current consumption of several mA in the early days; recently and continuing, a lower voltage is required, a smaller current consumption, for example hundreds of μA, is required, and power consumption has fallen to 1 mW or less. For example, in the case of a CMOS temperature sensor circuit, power consumption is about 120 μW (for example, Non-Patent Reference 1).

In addition, as conventional related technology, a voltage generating circuit using a field effect transistor for generating a voltage proportional to absolute temperature is available, wherein stable operation is available at a higher temperature than 80° C. (for example, Patent Reference 1).

[Non-Patent Reference 1] P. Krummenacher and H. Oguey, “Smart temperature sensor in CMOS technology”, Sensors and Actuators, Vol. A21-A23, pp 636-638, 1990

[Patent Reference 1] JPA 2001-284464

[Description of the Invention]

[Problem(s) to be solved by the Invention]

However, problems of the conventional technology include the power consumption being still great, a temperature detection error being generated due to heat generated by the temperature sensor, degradation of battery life in the case of a battery driven system, an increase in power consumption of a system when the temperature sensor is added to a VLSI chip, and the like. Accordingly, a temperature detecting circuit that consumes as little power as possible is required.

### SUMMARY OF THE INVENTION

In view of the problems described above, the present invention provides a highly precise temperature detecting circuit that is capable of operating at a low voltage and consumes low power by using a voltage source circuit that has a positive or a negative temperature coefficient using a difference of the work functions of field effect transistors, a reference voltage source circuit having zero temperature coefficient using a difference of the work functions of field effect transistors, and an operation amplifier that performs subtraction and amplification of an obtained difference voltage, substantially obviating one or more of the problems caused by the limitations and disadvantages of the related art.

Features of embodiments of the present invention are set forth in the description that follows, and in part will become apparent from the description and the accompanying drawings, or may be learned by practice of the invention according to the teachings provided in the description. Problem solutions provided by an embodiment of the present invention will be realized and attained by a temperature detecting circuit particularly pointed out in the specification in such full, clear, concise, and exact terms as to enable a person having ordinary skill in the art to practice the invention.

To achieve these solutions and in accordance with an aspect of the invention, as embodied and broadly described herein, an embodiment of the invention provides a temperature detecting circuit as follows.

[Means for Solving the Problem]

The temperature detecting circuit according to an embodiment of the present invention includes

a first voltage source circuit that generates the first voltage that has a temperature coefficient using a work function difference of the gate electrodes of two field effect transistors,

a second voltage source circuit that generates a predetermined reference voltage independent of temperature change using a work function difference of the gate electrodes of two or more field effect transistors, and

a subtracter circuit that obtains a difference voltage, which is a voltage difference between the first voltage and the reference voltage, and amplifies the difference voltage.

Specifically, the first voltage source circuit includes a first field effect transistor that has a high concentration n-type gate, and a second field effect transistor that has a high concentration p-type gate for generating the first voltage that has a negative temperature coefficient using the work function difference of the gate electrodes of the first and the second field effect transistors that have polysilicon gates of different conductive polarities.

Further, the first voltage source circuit may be constituted by the first field effect transistor that has the high concentration n-type gate, and a second field effect transistor that has a low concentration n-type gate for generating the first voltage that has a positive temperature coefficient using the work function difference of the gate electrodes of the first and the second field effect transistors that have polysilicon gates of the same conductive polarity.

Channel lengths of the first and the second field effect transistors are made different.

Further, the second voltage source circuit includes a third field effect transistor that has a high concentration n-type gate, and a fourth field effect transistor that has a high concentration p-type gate for generating the reference voltage independent of temperature change using the work function difference of the gate electrodes of the third and the fourth field effect transistors that have polysilicon gates of different conductive polarities.

Channel lengths of the third and the fourth field effect transistors are made different.

Specifically, the ratio of the channel lengths of the third and the fourth field effect transistors is selected so that the reference voltage is independent of temperature change.

Further, the second voltage source circuit may be constituted by

a first voltage generating unit that includes a first field effect transistor that has a high concentration n-type gate, and a second field effect transistor that has a low concentration n-type gate for generating a first voltage that has a positive temperature coefficient using the work function difference of gate electrodes of the first and the second field effect transistors that have a polysilicon gate of the same conductive polarity, and

a reference voltage generating unit that includes a third field effect transistor that has a high concentration n-type gate, and a fourth field effect transistor that has a high concentration p-type gate for generating a second voltage that has a negative temperature coefficient using the work function difference of gate electrodes of the third and the fourth field effect transistors that have polysilicon gates of different conductive polarities, and for generating the reference voltage independent of temperature change by adjusting inclination of the temperature coefficients of the first voltage and the second voltage such that the temperature coefficients may offset each other.

In this case, the first voltage generating unit serves as the first voltage source circuit.

Further, an impedance conversion circuit for converting impedance of the first voltage and the reference voltage may be provided.

Further, the first voltage source circuit includes a voltage adjustment circuit that performs voltage adjustment by stepping up or stepping down the first voltage.

Further, the second voltage source circuit includes a voltage adjustment circuit that performs voltage adjustment by stepping up or stepping down the reference voltage.

Further, the first voltage generating unit includes a first voltage adjustment circuit that performs voltage adjustment by stepping up or stepping down the first voltage, and the reference voltage generating unit includes a second voltage adjustment circuit that performs voltage adjustment by stepping up or stepping down the reference voltage.

Specifically, the voltage adjustment circuit is constituted by two or more resistance circuits for performing voltage adjustment, wherein the resistance is varied by trimming.

Specifically, each of the first and the second voltage adjustment circuits is constituted by two or more resistance circuits for performing voltage adjustment, wherein the resistance is varied by trimming.

Further, the first and the second voltage source circuits, and the subtracter circuit are integrated in one IC.

[Effect of the Invention]

The temperature detecting circuit of the present invention as embodied includes

the first voltage source circuit that generates the first voltage that has a temperature coefficient using the work function difference of the gate electrodes of two field effect transistors,

the second voltage source circuit that generates the predetermined reference-voltage independent of temperature change using the work function difference of the gate electrodes of two or more field effect transistors, and

the subtracter circuit that obtains the difference voltage between the first voltage and the reference voltage, and amplifies the difference voltage. In this way, a highly precise temperature detecting circuit capable of operating at a low voltage and with low power is realized.

### BRIEF DESCRIPTION OF THE DRAWINGS

FIG. 1 is a block diagram of an example of a temperature detecting circuit according to a first embodiment of the present invention;

FIG. 2 is a graph showing properties of voltages shown in FIG. 1 as temperature changes;

FIG. 3 is a circuit diagram of an example of a first voltage source circuit 2 shown in FIG. 1;

FIG. 4 is a graph showing an example of temperature characteristics of a voltage VPN;

FIG. 5 is a graph showing an example of a relationship between the ratio of channel lengths L of field effect transistors M1 and M2 and a temperature coefficient TCR of the voltage VPN;

FIG. 6 is a circuit diagram of an example of a second voltage source circuit 3 shown in FIG. 1;

FIG. 7 is a circuit diagram of another example of the second voltage source circuit 3 shown in FIG. 1;

FIG. 8 is a circuit diagram of another example of the second voltage source circuit 3 shown in FIG. 1;

FIG. 9 is a circuit diagram of another example of the first voltage source circuit 2 shown in FIG. 1;

FIG. 10 is a circuit diagram of another example of the second voltage source circuit 3 shown in FIG. 1;

FIG. 11 is a circuit diagram of another example of the first voltage source circuit 2 shown in FIG. 1;

FIG. 12 is a circuit diagram of another example of the second voltage source circuit 3 shown in FIG. 1;

FIG. 13 is a circuit diagram of another example of the second voltage source circuit 3 shown in FIG. 1;

FIG. 14 is a circuit diagram of another example of the second voltage source circuit 3 shown in FIG. 1;

FIG. 15 is a circuit diagram of a specific example of the temperature detecting circuit 1 shown in FIG. 1;

FIG. 16 is a block diagram showing a modification of the temperature detecting circuit according to the first embodiment of the present invention;

FIG. 17 is a block diagram of an example of the temperature detecting circuit according to a second embodiment of the present invention;

FIG. 18 is a graph showing properties of voltages shown in FIG. 17 as the temperature changes;

FIG. 19 is a circuit diagram of an example of a first voltage source circuit 2a shown in FIG. 17;

FIG. 20 is a graph showing temperature characteristics of a voltage VNN shown in FIG. 19;

FIG. 21 is a circuit diagram showing another example of the first voltage source circuit 2a shown in FIG. 17;

FIG. 22 is a circuit diagram showing an example of a second voltage source circuit 3a shown in FIG. 17;

FIG. 23 is a circuit diagram showing a specific example of a temperature detecting circuit 1a shown in FIG. 17; and

FIG. 24 is a circuit diagram showing a configuration example of a resistor.

### DESCRIPTION OF THE PREFERRED EMBODIMENTS

In the following, embodiments of the present invention are described with reference to the accompanying drawings.

### First Embodiment

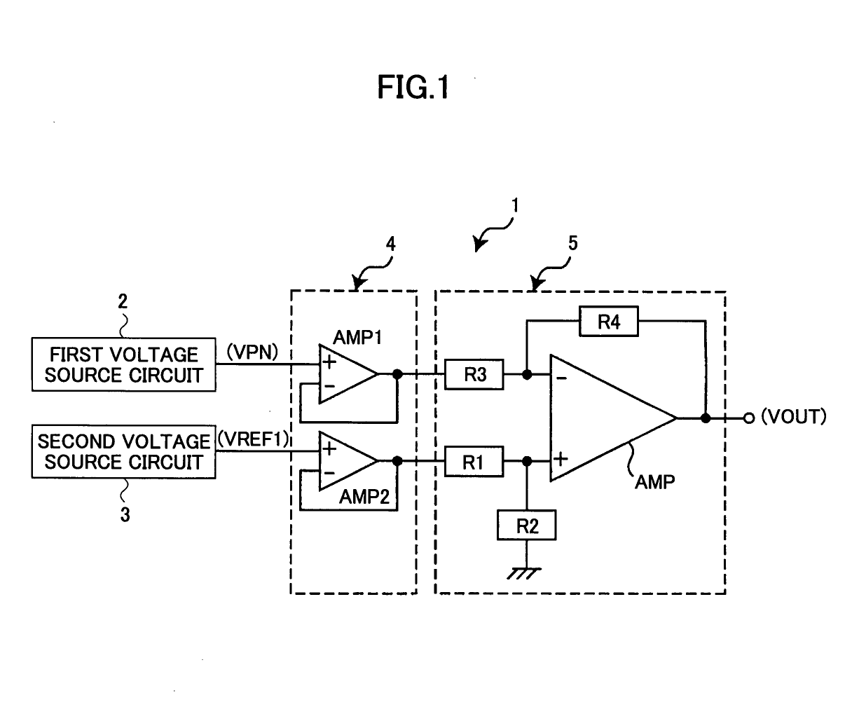

FIG. 1 is a block diagram of an example of a temperature detecting circuit 1 according to a first embodiment of the present invention.

The temperature detecting circuit 1 includes a first voltage source circuit 2, a second voltage source circuit 3, an impedance conversion circuit 4, and a subtracter circuit 5. The first voltage source circuit 2 generates and outputs a voltage VPN that has a negative temperature coefficient using a difference of the work functions of gate electrodes of two field effect transistors. The second voltage source circuit 3 generates and outputs a reference voltage VREF1 independent of temperature change using a difference of the work functions of gate electrodes of two or more field effect transistors. The impedance conversion circuit 4 performs impedance conversion of the voltage VPN and the reference voltage VREF1, and outputs the voltages VPN and VREF1 to the subtracter circuit 5. The subtracter circuit 5 obtains a voltage difference (difference voltage) between the reference voltage VREF1 and the voltage VPN that are provided by the impedance conversion circuit 4, amplifies the difference voltage, and outputs the amplified difference voltage as an output voltage VOUT. In this way, temperature sensitivity is raised and low power operations are realized.

The impedance conversion circuit 4 includes operation amplifiers AMP1 and AMP2. The voltage VPN is provided to a non-inverting input terminal of the operation amplifier AMP1, and the output terminal of the operation amplifier AMP1 is connected to a corresponding input terminal of the subtracter circuit 5. Further, the reference voltage VREF1 is provided to a non-inverting input terminal of the operation amplifier AMP2, and the output terminal of the operation amplifier AMP2 is connected to the other input terminal of the subtracter circuit 5. The output terminal of the operation amplifier AMP1 is further connected to the inverting input terminal of the operation amplifier AMP1 such that a voltage follower is formed. Similarly, the output terminal of the operation amplifier AMP2 is further connected to the inverting input terminal of the operation amplifier AMP2 such that a voltage follower is formed.

Further, the subtracter circuit 5 includes an operation amplifier AMP and resistors R1 through R4. The resistor R2 is connected between the non-inverting input terminal of the operation amplifier AMP, and a grounding voltage. The resistor R4 is connected between the output terminal of the operation amplifier AMP and the inverting input terminal of the operation amplifier AMP. Further, the reference voltage VREF1, impedance of which has been converted, is provided to the non-inverting input terminal of the operation amplifier AMP through the resistor R1. The voltage VPN, impedance of which has been converted, is provided to the inverting input terminal of the operation amplifier AMP through the resistor R3.

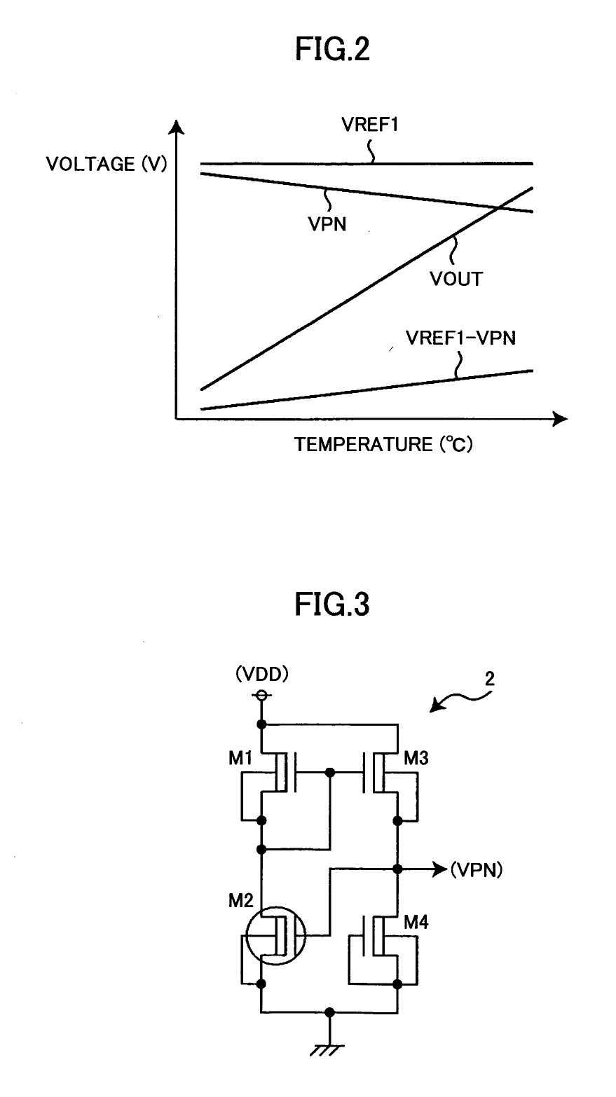

FIG. 2 shows properties of the voltages (VPN, VREF1, VOUT, and VREF1−VPN) over temperature change when the temperature detecting circuit 1 is structured as shown in FIG. 1. As shown in FIG. 2, the voltage VPN has a negative temperature coefficient, and the reference voltage VREF1 does not have a temperature coefficient or a zero coefficient. Accordingly, the difference between VREF1 and VPN (VREF1−VPN) has a positive temperature coefficient. The output voltage VOUT is obtained by amplifying the difference voltage (VREF1−VPN), the output voltage VOUT having a positive temperature coefficient that is greater than that of the difference voltage (VREF1−VPN).

FIG. 3 is a circuit diagram of an example of the first voltage source circuit 2 shown in FIG. 1.

In FIG. 3, the first voltage source circuit 2 includes n-channel type field effect transistors M1 through M4, which are depletion type transistors. In addition, the field effect transistor M1 is called the first field effect transistor, the field effect transistor M2 is called the second field effect transistor, and the voltage VPN is called the first voltage. Between a supply voltage VDD and the grounding voltage, the field effect transistors M1 and M2 are connected in series, and the field effect transistors M3 and M4 are connected in series. The gate of the field effect transistor M1 is connected to the gate of the field effect transistor M3, and the connection section is connected to the source of the field effect transistor M1. The gate of the field effect transistor M2 is connected to the connection section of the field effect transistors M3 and M4, and the connection section serves as an output terminal where the voltage VPN is output. Further, the source and the gate of the field effect transistor M4 are connected such that a constant current source is formed.

The field effect transistors M1 and M2 are made of the same substrate and have the same channel dope impurity concentration; they are formed in a p-well of an n-type substrate, and are connected such that the substrate voltage is equal to the source voltage. The field effect transistor M1 has a high concentration n-type gate, and the channel dope impurity concentration is adjusted so that depletion operations may be carried out; accordingly, the constant current source is formed by connecting the gate and the source. The field effect transistor M2 has a high concentration p-type gate, to which a drain voltage is provided by the source follower circuit constituted by the field effect transistors M3 and M4, which are n-channel type field effect transistors; and the voltage between the gate and the source of the field effect transistor M2 is output as the voltage VPN.

By designing so that transistor sizes width/length (W/L) of the field effect transistors M1 and M2 are equal, the field effect transistors M1 and M2 serve as a field effect transistor pair. Since the same current flows to the field effect transistor pair, the voltage VPN that is the voltage between the gate and the source of the field effect transistor M2 becomes equal to a difference of gate work functions of the field effect transistors M1 and M2, and has a negative temperature coefficient due to a difference in temperature characteristics of the gate work functions of the field effect transistors M1 and M2.

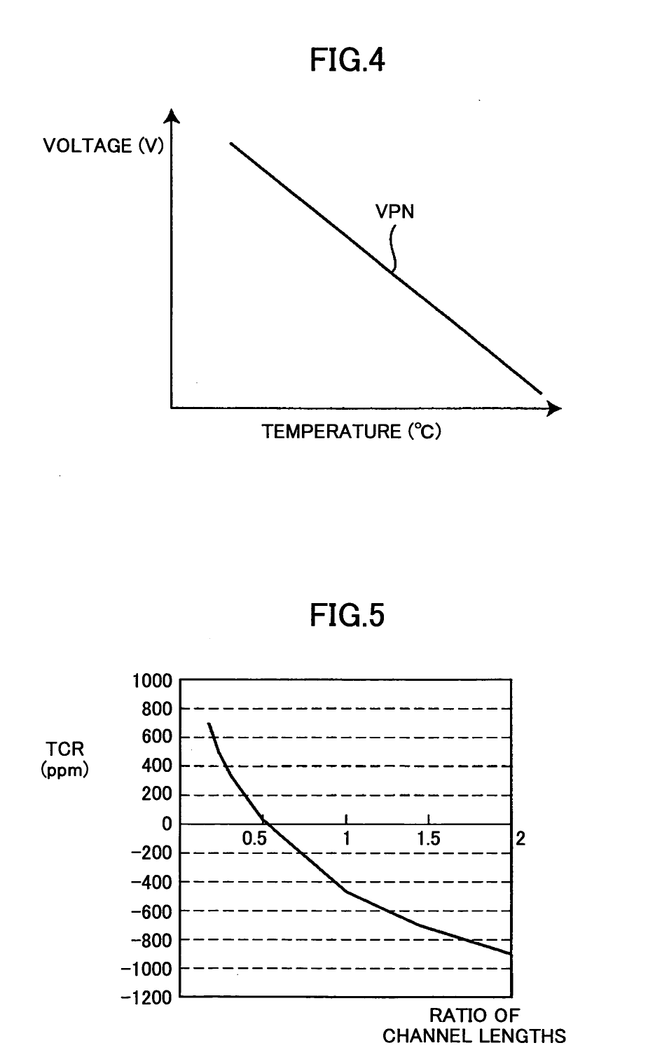

FIG. 4 shows an example of the temperature characteristics of the voltage VPN, wherein the horizontal axis represents temperature (C), the vertical axis represents voltage (V), and the temperature sensitivity (temperature coefficient) of the voltage VPN is, e.g., −0.49 mV/° C.

Here, the temperature coefficient of the voltage VPN can be altered by changing the ratio of the channel lengths of the field effect transistor pair M1 and M2 that have polysilicon gates, the conductive polarities of which differ. Generally, in order to improve precision of the output, which is the important property of the temperature detecting circuit, it is desirable to enlarge voltage change (temperature coefficient) corresponding to temperature change as much as possible, and to make sensitivity to temperature change high.

FIG. 5 shows an example of a relationship between the ratio of the channel lengths L of the field effect transistors M1 and M2, and the temperature coefficient TCR of the voltage VPN.

As shown in FIG. 5, since the temperature coefficient TCR of the output voltage VPN changes according to the ratio of the channel lengths L, a desired temperature coefficient can be obtained by adjusting the ratio of the channel lengths L. That is, the temperature coefficient TCR of the voltage VPN can be increased by choosing a proper ratio of the channel lengths L, and precision of temperature detection by the temperature detecting circuit can be improved.

Further, as shown in FIG. 5, the temperature coefficient TCR of the voltage VPN can be made zero by properly adjusting the ratio of the channel lengths of the field effect transistors M1 and M2. Accordingly, the second voltage source circuit 3 shown in FIG. 1 can be formed by selecting the ratio of the channel lengths of the field effect transistors M1 and M2 such that the temperature coefficient TCR of the voltage VPN may become 0.

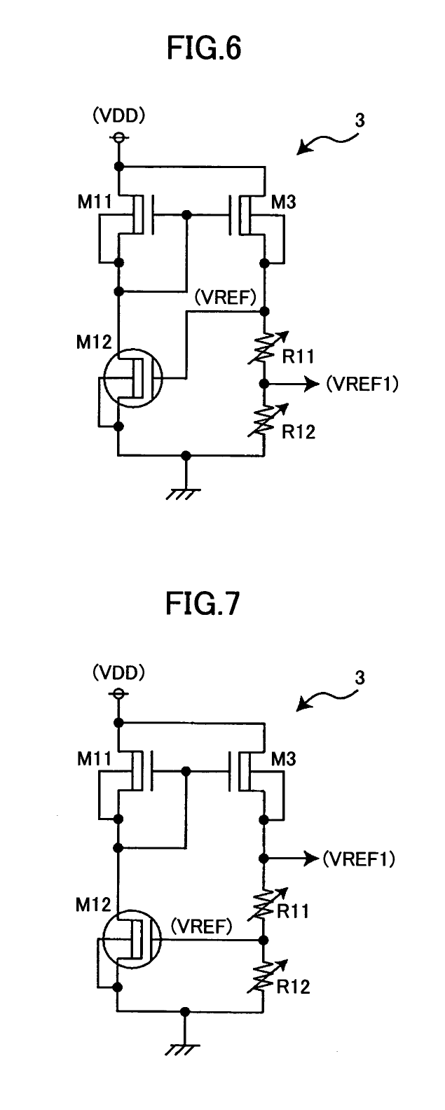

FIG. 6 shows an example of the second voltage source circuit 3 implemented in this way, wherein items that are same as or similar to those given in FIG. 3 are indicated with the same reference numbers.

As shown in FIG. 6, the second voltage source circuit 3 includes n-channel type field effect transistors M11, M12, and M3, and resistors R11 and R12, wherein the field effect transistors M11, M12, and M3 are depletion type transistors. In addition, the field effect transistor M11 is called the third field effect transistor, and the field effect transistor M12 is called the fourth field effect transistor; and the resistors R11 and R12 constitute a voltage adjustment circuit.

Between the supply voltage VDD and the grounding voltage, the field effect transistors M11 and M12 are connected in series; and the field effect transistor M3, the resistor R11, and the resistor R12 are connected in series. The gates of the field effect transistors M11 and M3 are connected, and this connection section is connected to the source of the field effect transistor M11. The gate of the field effect transistor M12 is connected to the connection section of the field effect transistor M3 and the resistor R11, and a reference voltage VREF is provided to this connection section. The reference voltage VREF is divided by the resistors R11 and R12, and the divided voltage is output as a reference voltage VREF1.

The field effect transistors M11 and M12 are made of the same substrate and have the same channel dope impurity concentration; they are formed in a p-well of an n-type substrate, and are connected such that the substrate voltage is equal to the source voltage. The field effect transistor M11 has a high concentration n-type gate, and the channel dope impurity concentration is adjusted so that depletion operation may be carried out; accordingly, the constant current source is formed by connecting the gate and the source. The field effect transistor M12 has a high concentration p-type gate, to which gate a drain voltage is provided from the source follower circuit constituted by the field effect transistor M3, which is an n-channel type field effect transistor; and the voltage between the gate and the source of the field effect transistor M12 is output as the voltage VREF.

Since the same current flows to the field effect transistors M11 and M12, the voltage between the gate and the source of the field effect transistor M12 turns into the reference voltage VREF. The ratio of the channel lengths of the field effect transistors M11 and M12 is selected so that the temperature coefficient TCR of the reference voltage VREF may become 0. In this way, the reference voltage VREF1 can be adjusted by changing the ratio of the resistances of the resistors R11 and R12.

Although the reference voltage VREF1 is obtained by stepping down the reference voltage VREF in FIG. 6, the reference voltage VREF1 may be obtained from the connection section of the field effect transistor M3 and the resistor R11 as shown in FIG. 7, wherein the gate of the field effect transistor M12 is connected to the connection section of the resistors R11 and R12, where the reference voltage VREF is then provided. In this way, the reference voltage VREF1 can be made greater than the reference voltage VREF, and voltage adjustment can be performed by changing the ratio of the resistances of the resistors R11 and R12.

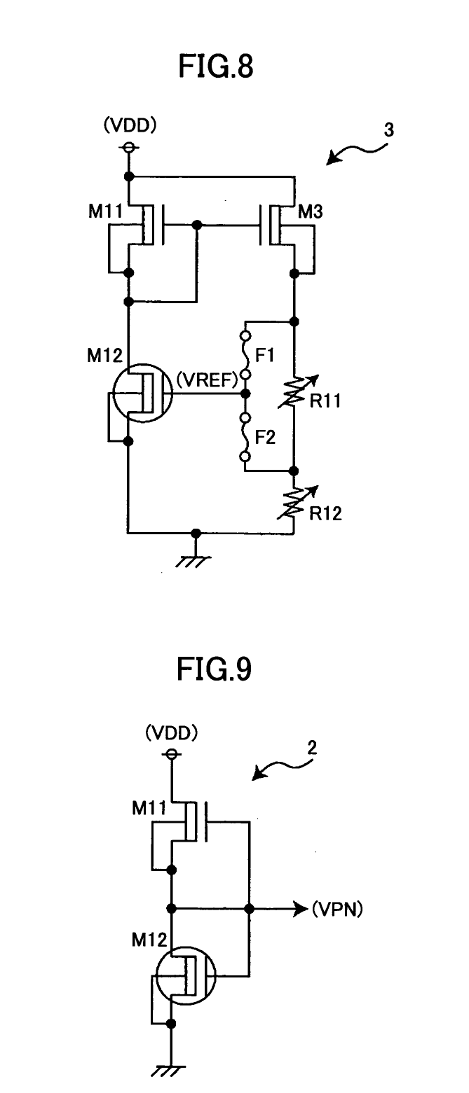

Further, the voltage adjustment of the reference voltage VREF1 can be carried out by stepping down or by stepping up the reference voltage VREF by selectively disconnecting a fuse as shown in FIG. 8.

In FIG. 8, the second voltage source circuit 3 includes the n-channel type field effect transistors M11, M12, and M3, the resistors R11 and R12, and fuses F1 and F2. In addition, the resistors R11 and R12 and the fuses F1 and F2 constitute a voltage adjustment circuit. A series circuit of the fuses F1 and F2 is connected in parallel with the resistor R11, and the gate of the field effect transistor M12 is connected to the connection section of the fuses F1 and F2.

In this way, if only the fuse F2 is disconnected and the reference voltage VREF1 is output from the connection section of the resistor R11 and R12, the circuit of FIG. 8 works the same as the circuit shown in FIG. 6. If only the fuse F1 is disconnected and the reference voltage VREF1 is output from the connection section of the field effect transistor M3 and the resistor R11, the circuit of FIG. 8 works the same as the circuit shown in FIG. 7. That is, the circuit of FIG. 8 is capable of adjusting the reference voltage VREF1 in a wider range because the reference voltage VREF can be stepped up or down as compared with the circuits of FIG. 6 and FIG. 7. Although the reference voltage VREF1 is obtained by stepping up or down the reference voltage VREF in the circuits as shown in FIGS. 6, 7, and 8, the reference voltage VREF may be used as the reference voltage VREF1; in this case, VREF=VREF1 can be obtained by the same circuit as shown in FIG. 3, but the field effect transistors M1 and M2 in FIG. 3 are replaced by the field effect transistors M11 and M12.

FIG. 9 is a circuit diagram showing another example of the first voltage source circuit 2 of FIG. 1. Where items in FIG. 9 are the same as or similar to those shown in FIG. 3, the same reference numbers are given.

In FIG. 9, the first voltage source circuit 2 includes the n-channel type field effect transistors M1 and M2, which are of a depletion type. Between the supply voltage VDD and the grounding voltage, the field effect transistors M1 and M2 are connected in series. The gates of the field effect transistors M1 and M2 are connected, and the connection section serves as the output terminal for outputting the voltage VPN.

The field effect transistors M1 and M2 are made of the same substrate and have the same channel dope impurity concentration; they are formed in a p-well of an n-type substrate, and are connected such that the substrate voltage is equal to the source voltage. The field effect transistor M1 has a high concentration n-type gate, and the channel dope impurity concentration is adjusted so that depletion operation may be carried out; accordingly, the constant current source is formed by connecting the gate and the source. The field effect transistor M2 has a high concentration p-type gate, wherein the gate and the drain are connected, and the voltage between the gate and the source of the field effect transistor M2 is output as the voltage VPN. Since the field effect transistors M1 and M2 of FIG. 9 are designed so that the transistor sizes W/L may become equal, the field effect transistors M1 and M2 serve as a field effect transistor pair, and the same current flows to the field effect transistor pair. Accordingly, the voltage between the gate and the source of the field effect transistor M2 turns into the voltage VPN that is the difference of the gate work functions of the field effect transistors M1 and M2.

Further, the second voltage source circuit 3 as shown in FIG. 1 can be formed by selecting the ratio of the channel lengths of the field effect transistors M1 and M2 of FIG. 9 as in the case of FIG. 3, so that the temperature coefficient TCR of the voltage VPN may be made zero.

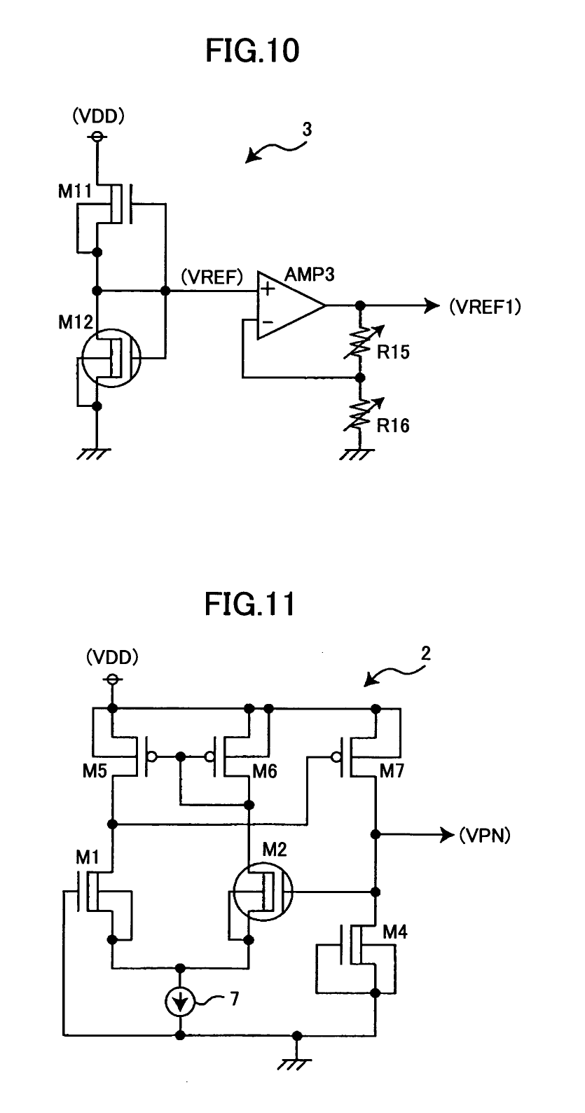

FIG. 10 shows an example of the second voltage source circuit 3 implemented in this way, wherein items that are the same as, or similar to those in FIG. 6 are given the same reference numbers.

The second voltage source circuit 3 shown in FIG. 10 includes the n-channel type field effect transistors M11 and M12, an operation amplifier AMP3, and resistors R15 and R16. In addition, the operation amplifier AMP3 and the resistors R15 and R16 constitute the voltage adjustment circuit. The field effect transistors M11 and M12 are connected in series between the supply voltage VDD and the grounding voltage, the gates of the field effect transistors M11 and M12 are connected, the connection section is connected to the connection section of the field effect transistors M11 and M12, and the connection section provides the reference voltage VREF.

The reference voltage VREF is provided to the non-inverting input terminal of the operation amplifier AMP3, and the output terminal of the operation amplifier AMP3 is connected to the non-inverting input terminal of the operation amplifier AMP through the resistor R1 of the subtracter circuit 5 (Ref. FIG. 1). Between the output terminal of the operation amplifier AMP3 and the grounding voltage, the resistors R15 and R16 are connected in series, and the connection section of the resistors R15 and R16 is connected to the inverting input terminal of the operation amplifier AMP3. From the output terminal of the operation amplifier AMP3, the reference voltage VREF1, which is stepped up from the reference voltage VREF and impedance converted by the resistors R15 and R16, is output.

When the second voltage source circuit 3 structured as shown in FIG. 10 is used, the operation amplifier AMP2 of the impedance conversion circuit 4 of FIG. 1 can be dispensed with. In addition, VREF1 is generated by stepping up the reference voltage VREF in FIG. 10; however the reference voltage VREF may serve as the reference voltage VREF1, in which case, VREF=VREF1 can be obtained by the same circuit as shown in FIG. 9, but the field effect transistors M1 and M2 in FIG. 9 are replaced by the field effect transistors M11 and M12. However, in this case, the operation amplifier AMP2 of the impedance conversion circuit 4 is necessary.

FIG. 11 is a circuit diagram showing another example of the first voltage source circuit 2 of FIG. 1. Items in FIG. 11, that are the same as or similar to those shown in FIG. 3 and FIG. 9 bear the same reference numbers.

In FIG. 11, the first voltage source circuit 2 includes n-channel type field effect transistors M1, M2, and M4, p-channel type field effect transistors M5, M6, and M7, and a constant current source 7. The field effect transistors M1 and M2 are made of the same substrate and have the same channel dope impurity concentration; they are formed in a p-well of an n-type substrate; and they are connected such that the substrate voltage is equal to the source voltage. The field effect transistor M1 has a high concentration n-type gate, and the field effect transistor M2 has a high concentration p-type gate.

By designing such that the transistor size W/L of the field effect transistors M1 and M2 may become equal, the field effect transistors M1 and M2 serve as a field effect transistor pair. The field effect transistor pair M1 and M2 serves as input transistors of a differential amplifier. The field effect transistors M5 and M6, which are of p-channel type, constitute a current mirror circuit. A feedback loop for the output the voltage VPN is formed between the field effect transistors M7, which is of p-channel type, and the differential amplifier. The field effect transistor pair M1 and M2 serves as the input transistors of the differential amplifier, and the differential amplifier has an input offset of the voltage VPN that has a negative temperature coefficient.

Further, the second voltage source circuit 3 of FIG. 1 can be formed by selecting the ratio of the channel lengths of the field effect transistors M1 and M2 of FIG. 11 so that the temperature coefficient TCR of the voltage VPN may become 0 as in the case of FIG. 3.

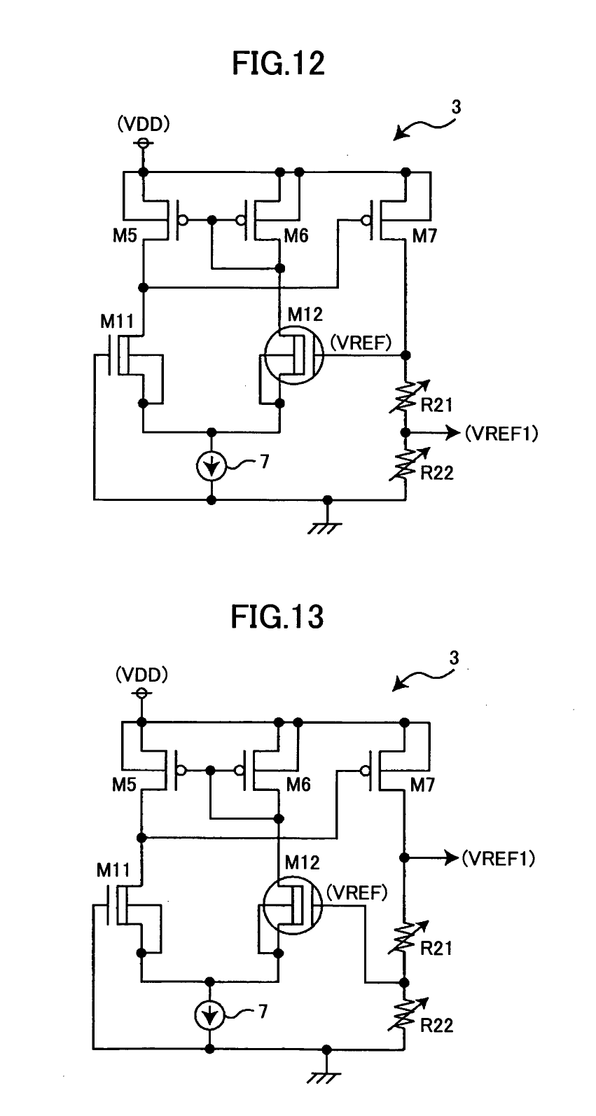

FIG. 12 is a circuit diagram of an example of the second voltage source circuit 3 structured as described above. Items in FIG. 12 that are the same as or similar to those in FIG. 6 and FIG. 11 bear the same reference numbers.

The second voltage source circuit 3 shown in FIG. 12 includes the n-channel type field effect transistors M11 and M12, the p-channel type field effect transistors M5, M6, and M7, the constant current source 7, and resistors R21 and R22. Here, the resistors R21 and R22 constitute the voltage adjustment circuit.

The field effect transistors M11 and M12 constitute input transistors of the differential amplifier; further, the p-channel type field effect transistors M5 and M6 constitute a current mirror circuit. The output voltage VREF of the differential amplifier is fed back through the p-channel type field effect transistor M7. The field effect transistors M11 and M12 serve as the input transistors of the differential amplifier, and the differential amplifier has an input offset of the reference voltage VREF, the temperature coefficient of which is 0. The reference voltage VREF is divided by the resistors R21 and R22, and the divided voltage is output as the reference voltage VREF1.

Although the reference voltage VREF1 is obtained by stepping down the reference voltage VREF in FIG. 12, VREF1 can be obtained by stepping up VREF as shown in FIG. 13, wherein the gate of the field effect transistor M12 is connected to the connection section of the resistors R21 and R22, where the reference voltage VREF is provided, and the reference voltage VREF1 is taken out from the connection section of the field effect transistor M7 and the resistor R21. In this way, by changing the ratio of the resistances of the resistors R21 and R22, the reference voltage VREF1 that is higher than the reference voltage VREF can be generated, and the voltage adjustment can be performed.

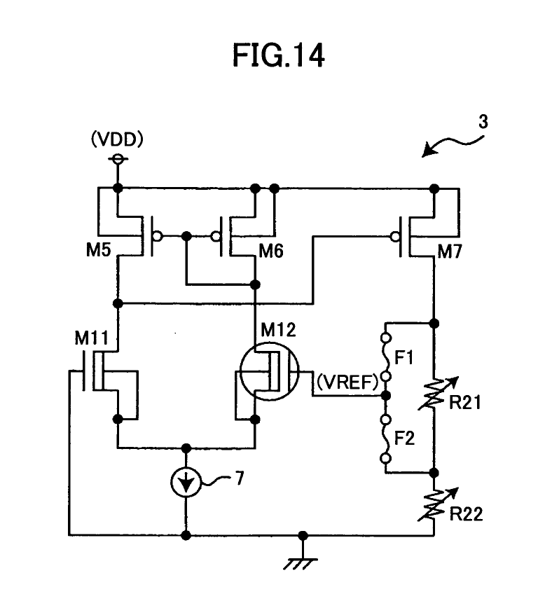

Further, the second voltage source circuit 3 of FIG. 12 and FIG. 13 may be structured such that the reference voltage VREF1 may be adjusted by stepping up or down the reference voltage VREF by providing the fuses F1 and F2 as shown in FIG. 14.

The second voltage source circuit 3 in FIG. 14 includes the n-channel type field effect transistors M11 and M12, the p-channel type field effect transistors M5, M6, and M7, the constant current source 7, the resistors R21 and R22, and the fuses F1 and F2. Here, the resistors R21 and R22, and the fuses F1 and F2 constitute the voltage adjustment circuit. The series circuit of the fuses F1 and F2 is connected in parallel with the resistor R21, and the gate of the field effect transistor M12 is connected to the connection section of the fuses F1 and F2.

With reference to FIG. 14, if the fuse F2 is disconnected (the fuse F1 being intact) and the reference voltage VREF1 is output from the connection section of the resistors R21 and R22, the circuit works the same as the circuit shown in FIG. 12. Otherwise, if the fuse F1 is disconnected (the fuse F2 being intact) and the reference voltage VREF1 is output from the connection section of the field effect transistor M7 and the resistor R21, the circuit works the same as the circuit shown in FIG. 13. The reference voltage VREF can be stepped up or down, as desired, to adjust the reference voltage VREF1, and the voltage adjustment range of the reference voltage VREF1 can be made greater than the cases shown in FIG. 12 and FIG. 13. In addition, although the reference voltage VREF1 is obtained by stepping up or down the reference voltage VREF in FIGS. 12 through 14, the reference voltage VREF may be used as the reference voltage VREF1. In this case, the same circuit as shown in FIG. 11 can be used, wherein the field effect transistors M1 and M2 are replaced by the field effect transistors M11 and M12.

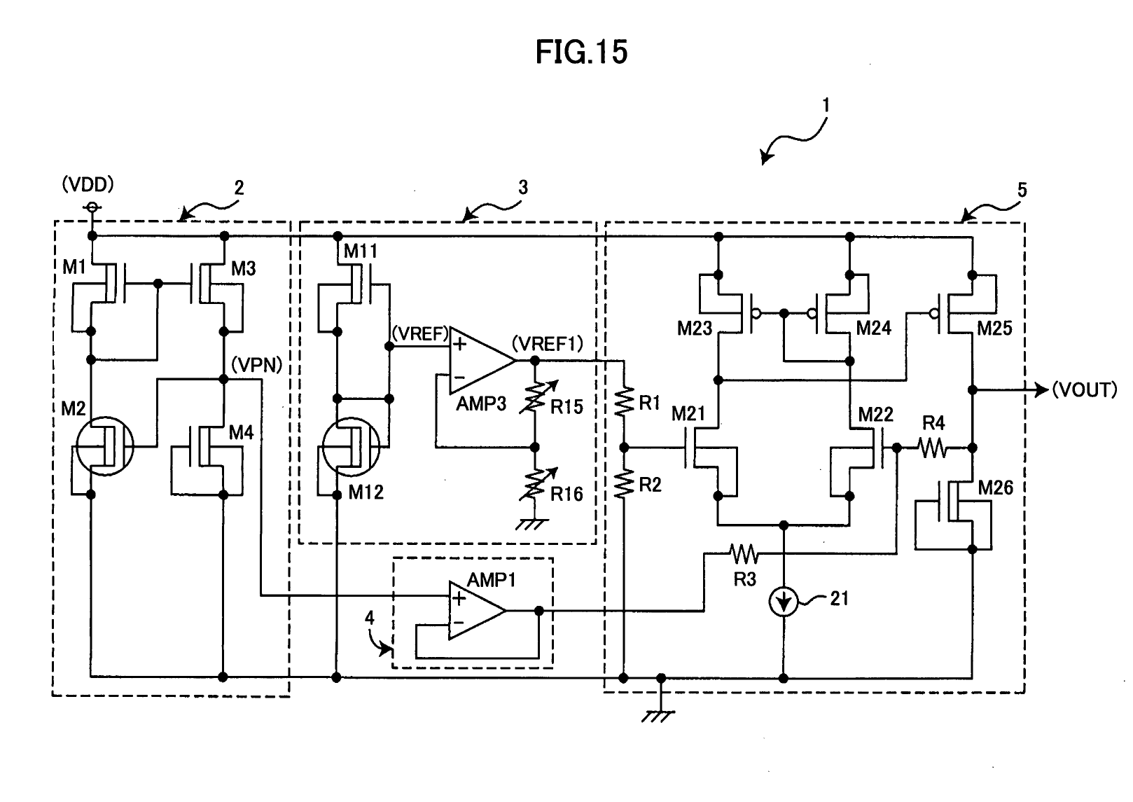

FIG. 15 is a circuit diagram showing a specific example of the temperature detecting circuit 1 of FIG. 1. The example shows the case wherein the circuit of FIG. 3 is used as the first voltage source circuit 2, and the circuit of FIG. 10 is used as the second voltage source circuit 3.

In FIG. 15, the first voltage source circuit 2 that includes the n-channel type field effect transistors M1 through M4 is the same as the circuit shown in FIG. 3, the explanation is not repeated. Further, the second voltage source circuit 3 that includes the n-channel type field effect transistors M11 and M12, the operation amplifier AMP3, and the resistors R15 and R16 is the same as the circuit shown in FIG. 10, the explanation is not repeated. Since the circuit of FIG. 10 is used as the second voltage source circuit 3, the impedance conversion circuit 4 includes the operation amplifiers AMP1, but excludes the operation amplifier AMP2 as described with reference to FIG. 10.

The subtracter circuit 5 includes the operation amplifier AMP, and the resistors R1 through R4. The operation amplifier AMP includes:

a differential amplification stage that includes

enhancement type n-channel type field effect transistors M21 and M22 that constitute a differential pair,

enhancement type p-channel type field effect transistors M23 and M24 that serve as loads of the n-channel type field effect transistors M21 and M22, respectively, and

a constant current source 21 that supplies constant current to the field effect transistors M21 and M22; and

an amplification stage that includes

an enhancement type p-channel type field effect transistor M25, and

a n-channel type field effect transistor M26 of the depletion type that serves as the constant current source. The gate of the field effect transistor M21 serves as the non-inverting input terminal of the operation amplifier AMP, and the gate of the field effect transistor M22 serves as the inverting input terminal of the operation amplifier AMP.

The sources of the field effect transistors M21 and M22 are connected, and between this connection section and the grounding voltage, the constant current source 21 is connected. The field effect transistor M23 is connected between the supply voltage VDD and the drain of the field effect transistor M21, and the field effect transistor M24 is connected between the supply voltage VDD and the drain of the field effect transistor M22. The field effect transistors M23 and M24 constitute the current mirror circuit, wherein the gates of the field effect transistors M23 and M24 are connected, and this connection section is connected to the drain of the field effect transistor M24.

Between the supply voltage VDD and the grounding voltage, the field effect transistors M25 and M26 are connected in series, and the gate of the field effect transistor M25 is connected to the connection section of the field effect transistors M23 and M21. Further, the gate and the source of the field effect transistor M26 are connected, and the connection section of the field effect transistors M25 and M26 serves as the output terminal of the operation amplifier AMP for providing the output voltage VOUT. The reference voltage VREF1 provided by the second voltage source circuit 3 is divided by the resistors R1 and R2, and the divided voltage is provided to the gate of the field effect transistor M21. The voltage VPN from the first voltage source circuit 2 is provided to the operation amplifier AMP1 that carries out impedance conversion, and then provided to the gate of the field effect transistor M22 through the resistor R3. Then, the output voltage VOUT of the operation amplifier AMP is fed back to the gate of the field effect transistor M22 through the resistor R4.

With the configuration described above, the voltages shown in FIG. 15 change as temperature changes as shown in FIG. 2. Since the voltage VPN has a negative temperature coefficient, it decreases with a temperature rise. On the other hand, since the temperature coefficient of the reference voltage VREF1 is zero, VREF1 does not change as the temperature changes, and stays at a fixed voltage. Accordingly, the difference VREF1-VPN has a positive temperature coefficient, and the difference VREF1−VPN is multiplied by a resistor ratio n, to be made into the output voltage VOUT as shown by the following formula (1).
VOUT=n×(VREF1−VPN) (1)

Here, the resistor ratio n is a ratio of a resistance r2 of the resistor R2 to a resistance r1 of the resistor R1, and where r1=r3 and r2=r4, n=r2/r1=r4/r3.

Here, the low voltage operation of the temperature detecting circuit 1 of FIG. 15 is specifically described using numeric values.

As described above, the temperature coefficient of the voltage VPN is about −0.49 mV/° C., which is a small value, and is required to be amplified in order to raise the temperature sensitivity of the temperature detecting circuit 1. If a temperature coefficient of, for example, 5 mV/° C. is required over a temperature range between 0 and 100° C. where the voltage VPN approximately ranges between 1 and 0.95 V, the voltage VPN has to be amplified about 10 times. If the voltage VPN is amplified by a factor of 10, the voltage VPN will become a very high voltage approximately ranging between 10 and 9.5 V, which is not desired in view of the targeted low voltage operation. Accordingly, the temperature detecting circuit 1 of FIG. 15 first generates the difference between the reference voltage VREF1 and the voltage VPN, and then the difference is amplified as shown by the formula (1). In this way, the targeted low voltage operation is realized.

Next, the minimum operating voltage Vmin of the temperature detecting circuit 1 of FIG. 15 is considered.

The minimum operating voltage Vmin of the temperature detecting circuit 1 of FIG. 15 is a sum of a voltage VdsM1 between the drain and the source of the field effect transistor M1, a voltage VgsM3 between the gate and the source of the field effect transistor M3, and the voltage VPN as expressed by the following formula (2).

$$\begin{matrix}Vmin = VdsM 1 + VgsM 3 + VPN \\ = ( VgsM 1 - VthM 1 ) + VgsM 3 + VPN \\ = - VthM 1 + VgsM 3 + VPN\end{matrix} \qquad ( 2 )$$

Here, VthM1 represents a threshold voltage of the field effect transistor M1, and VgsM1 represents a voltage between the gate and the source of the field effect transistor M1.

Here, since the gate and the source of the field effect transistor M1 are connected, the voltage VgsM1 is 0. When the threshold voltage of the field effect transistors M1 through M3 is −0.4 V, and the voltage VPN is 1 V, the minimum operating voltage Vmin is expressed by the following formula (3).

$$\begin{matrix}Vmin = - VthM 1 + VgsM 3 + VPN \\ = - ( - 0.4 ) + VgsM 3 + 1 \\ = 1.4 + VgsM 3\end{matrix} \qquad ( 3 )$$

Therefore, the minimum operating voltage Vmin is determined by the voltage VgsM3 between the gate and the source of the field effect transistor M3. For example, when the voltage VgsM3 is −0.4 V, circuit operation is attained at a low voltage that is about 1 V. In this case, since the consumed electric current of the temperature detecting circuit 1 is about 3 μA, power consumption is about 3 μA×1 V=3 μW. Thus, the temperature detecting circuit 1 according to the first embodiment realizes the low voltage operation and the low power operation.

In addition, with reference to FIG. 15, as the first voltage source circuit 2, one of the circuits shown by FIG. 9 and FIG. 11 may be used; and as the second voltage source circuit 3, any one of the circuits shown by FIGS. 6 through 8, and FIGS. 12 through 14 may be used.

However, when using any one of the circuits shown by FIGS. 6 through 8 and FIG. 12 through 14 as the second voltage source circuit 3, the reference voltage VREF1 from the second voltage source circuit 3 is provided to the resistor R1 after impedance conversion by the operation amplifier AMP2 of the impedance conversion circuit 4 as shown by FIG. 1.

Further, although the embodiment is described about the case wherein the impedance conversion circuit 4 is used, when impedance conversion is not required, the impedance conversion circuit 4 can be dispensed with. In this case, the voltage VPN from the first voltage source circuit 2 is directly provided to the resistor R3, and the reference voltage VREF1 from the second voltage source circuit 3 is directly provided the resistor R1.

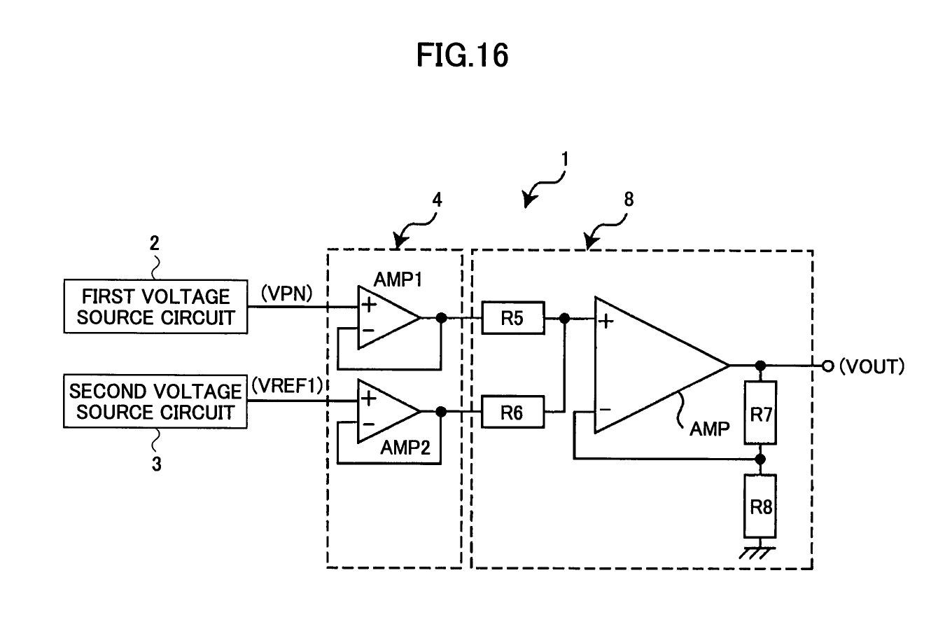

Further, although the embodiment is described about the case wherein the subtractor circuit is used, an adder circuit may be used instead. In this case, FIG. 1 is replaced by FIG. 16, wherein items that are the same as, or similar to those in FIG. 1 bear the same reference numbers, and the explanation thereof is not repeated.

The temperature detecting circuit 1 according to FIG. 16 includes the first voltage source circuit 2, the second voltage source circuit 3, the impedance conversion circuit 4, and an adder circuit 8. The impedance conversion circuit 4 performs impedance conversion of the voltage VPN and the reference voltage VREF1, and outputs the impedance converted voltages VPN and VREF1 to the adder circuit 8. In order to realize the low power operation and to raise the temperature sensitivity, the adder circuit 8 adds the voltage VPN from the first voltage source circuit 2 and the reference voltage VREF1 from the second voltage source circuit 3 that are provided through the impedance conversion circuit 4, amplifies the added voltage such that the output voltage VOUT is generated, and outputs the voltage VOUT.

The adder circuit 8 includes the operation amplifier AMP, and resistors R5 through R8, wherein the resistors R7 and R8 are connected in series between the output terminal of the operation amplifier AMP and the grounding voltage, and the connection section of the resistors R7 and R8 is connected to the inverting input terminal of the operation amplifier AMP. Further, the voltage VPN, impedance of which is converted, is provided to the non-inverting input terminal of the operation amplifier AMP through the resistor R5; and the reference voltage VREF1, impedance of which is converted, is provided to the non-inverting input terminal of the operation amplifier AMP through the resistor R6.

With the structure as described above, since the voltage VPN has a negative temperature coefficient, VPN decreases with temperature increase. On the other hand, since the reference voltage VREF1 has a zero temperature coefficient, VREF1 does not change with temperature, but stays at a fixed voltage. Here, the input voltage to the non-inverting input terminal of the operation amplifier AMP is (VPN+VREF1)/2 over all the temperature range. By carrying out negative feedback of the output of the operation amplifier AMP through the resistor R7 and R8, the output voltage VOUT becomes as expressed by the following the formula (4), i.e., the sum of the voltage VPN and the reference voltage VREF1.
VOUT={(VPN+VREF1)/2}×2=VPN+VREF1 (4)

### Second Embodiment

Although the circuit for generating the voltage VPN that has a negative temperature coefficient is used as the first voltage source circuit 2 in the first embodiment, a circuit that generates a voltage VTEMP that has a positive temperature coefficient may be used as the first voltage source circuit 2, which is described below as a second embodiment of the present invention.

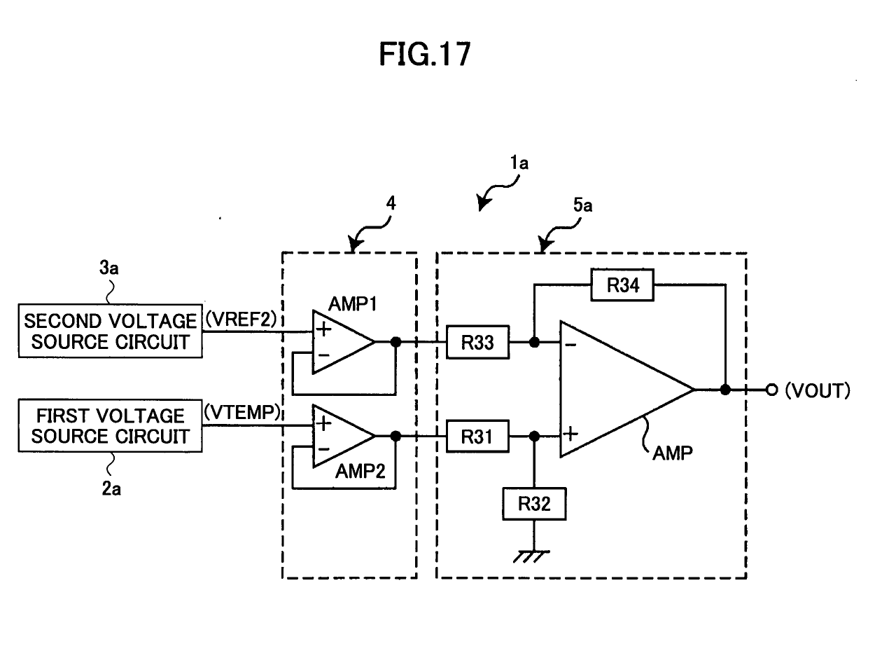

FIG. 17 is a block diagram of an example of a temperature detecting circuit 1a according to the second embodiment of the present invention. In FIG. 17, items that are the same as or similar to those in FIG. 1 bear the same reference numbers.

As shown in FIG. 17, the temperature detecting circuit 1a includes a first voltage source circuit 2a, a second voltage source circuit 3a, the impedance conversion circuit 4, and a subtracter circuit 5a. The first voltage source circuit 2a generates and outputs the voltage VTEMP that has a positive temperature coefficient related to change of environmental temperature using the work function difference of the gate electrodes of two field effect transistors. The second voltage source circuit 3a generates and outputs a reference voltage VREF2 independent of temperature change using the work function difference of the gate electrodes of two or more field effect transistors. The impedance conversion circuit 4 performs impedance conversion of the voltage VTEMP and the reference voltage VREF2, and outputs the impedance converted voltages VTEMP and VREF2 to the subtracter circuit 5a. In order to raise temperature sensitivity and realize low power operations, the subtracter circuit 5a obtains a difference voltage between the voltage VTEMP provided by the first voltage source circuit 2a and the reference voltage VREF2 provided by the second voltage source circuit 3a, the voltages VTEMP and VREF2 being provided through the impedance conversion circuit 4. The subtracter circuit 5a amplifies the difference voltage to generate the output voltage VOUT, and outputs the VOUT.

The impedance conversion circuit 4 includes the operation amplifiers AMP1 and AMP2, wherein the reference voltage VREF2 is provided to the non-inverting input terminal of the operation amplifier AMP1, and the output terminal of the operation amplifier AMP1 is connected to an input terminal of the subtracter circuit 5a. Further, the voltage VTEMP is provided to the non-inverting input terminal of the operation amplifier AMP2, and the output terminal of the operation amplifier AMP2 is connected to the other input terminal of the subtracter circuit 5a. The output terminal of the operation amplifier AMP1 is further connected to the inverting input terminal of the operation amplifier AMP1, forming a voltage follower. Similarly, the output terminal of the operation amplifier AMP2 is further connected to the inverting input terminal of the operation amplifier AMP2, forming a voltage follower.

Further, the subtracter circuit 5a includes the operation amplifier AMP and resistors R31 through R34. The resistor R32 is connected between the non-inverting input terminal of the operation amplifier AMP and the grounding voltage. The resistor R34 is connected between the output terminal of the operation amplifier AMP and the inverting input terminal of AMP. Further, the voltage VTEMP, impedance of which is converted, is provided to the non-inverting input terminal of the operation amplifier AMP through the resistor R31. The reference voltage VREF2, impedance of which is converted, is provided to the inverting input terminal of the operation amplifier AMP through the resistor R33.

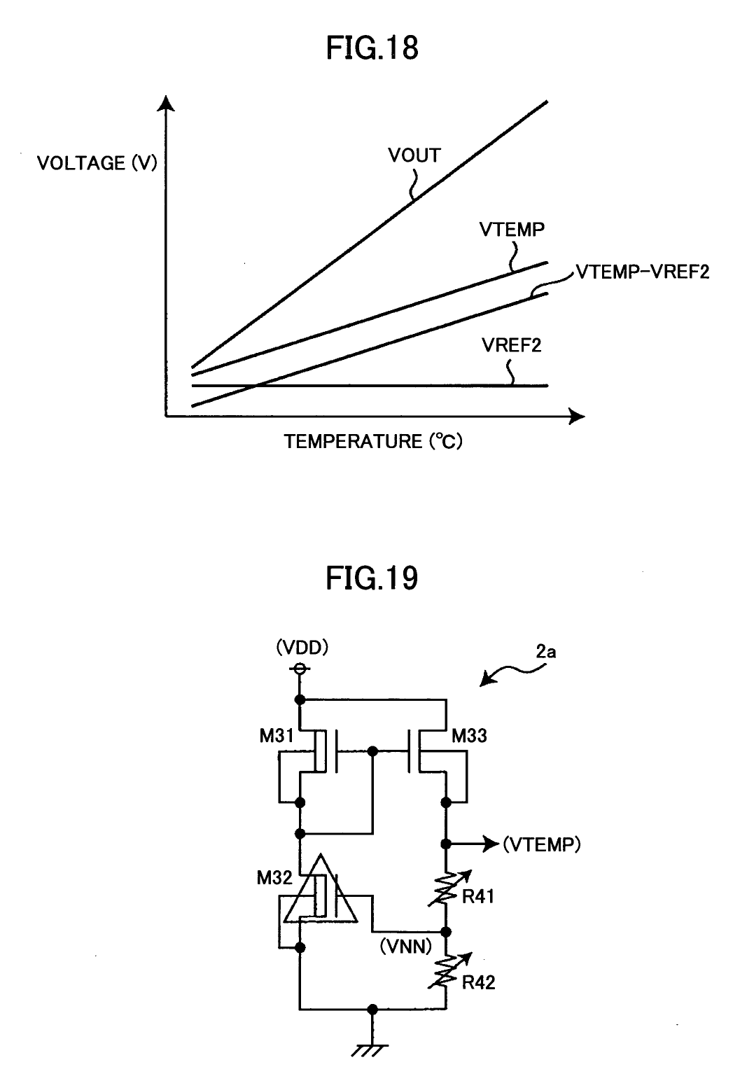

With the structure as described above, properties of the voltages shown in FIG. 17 over temperature change are as shown by FIG. 18. As shown in FIG. 18, the voltage VTEMP has a positive temperature coefficient, and the reference voltage VREF2 has a zero temperature coefficient. Accordingly, a difference voltage (VTEMP−VREF2) obtained by subtracting the reference voltage VREF2 from the voltage VTEMP has a positive temperature coefficient. The difference voltage is amplified to serve as the output voltage VOUT, the temperature coefficient of which is greater than that of the difference voltage (VTEMP−VREF2).

FIG. 19 is a circuit diagram showing an example of the first voltage source circuit 2a shown in FIG. 17.

As shown in FIG. 19, the first voltage source circuit 2a includes n-channel type field effect transistors M31 through M33 and resistors R41 and R42, the field effect transistors M31 and M32 being depletion type, the field effect transistor M33 being an enhancement type. Here, the field effect transistor M31 serves as the first field effect transistor, the field effect transistor M32 serves as the second field effect transistor, a voltage VNN serves as the first voltage, and the resistors R41 and R42 serve as the voltage adjustment circuit. Between the supply voltage VDD and the grounding voltage, the field effect transistors M31 and M32 are connected in series, and the field effect transistor M33 and the resistors R41 and R42 are connected in series. The gates of the field effect transistors M31 and M33 are connected, and this connection section is connected to the source of the field effect transistor M31. The gate of the field effect transistor M32 is connected to the connection section of the resistors R41 and R42. The output voltage VTEMP is taken out from the connection section of the field effect transistor M33 and the resistor R41.

The field effect transistors M31 and M32 are made of the same substrate and have the same channel dope impurity concentration; they are formed in a p-well of an n-type substrate, and are connected such that the substrate voltage is equal to the source voltage. The field effect transistor M31 has a high concentration n-type gate, and the channel dope impurity concentration is adjusted so that depletion operation may be carried out; accordingly, the constant current source is formed by connecting the gate and the source. The field effect transistor M32 has a low concentration n-type gate, to which a drain voltage is provided by the source follower circuit constituted by the field effect transistor M33, which is an n-channel type field effect transistor, and the resistors R41 and R42. The voltage between the gate and the source of the field effect transistor M32 is output as the voltage VNN, and the source voltage of the field effect transistor M33 is output as VTEMP.

By designing so that the transistor size

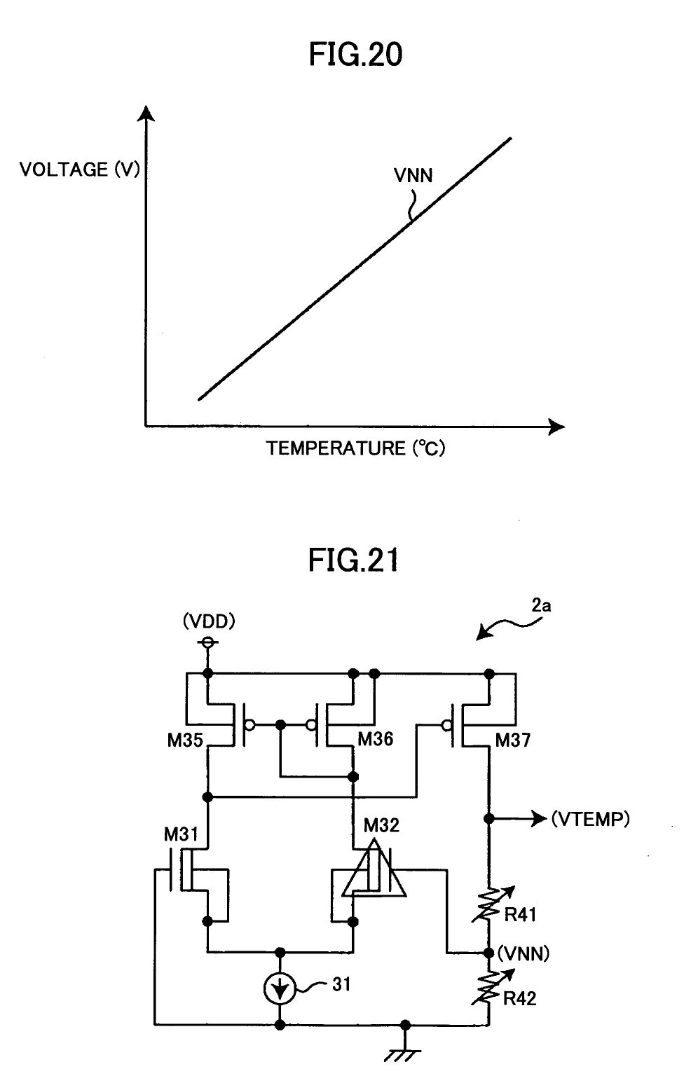

W/L of the field effect transistors M31 and M32 may become equal, the field effect transistors M31 and M32 serve as a field effect transistor pair. Since the same current flows to the field effect transistor pair, the voltage VNN that is the voltage between the gate and the source of the field effect transistor M32 becomes equal to a difference of gate work functions of the field effect transistors M31 and M32. The voltage VNN has a positive temperature coefficient due to the difference in the temperature characteristics of the gate work functions of the field effect transistors M31 and M32. Further, if resistances of the resistors R41 and R42 are called r41 and r42, respectively, the voltage VTEMP is equal to {(r41+r42)/r42}×VNN, and has a positive temperature coefficient greater than that of the voltage VNN by being amplified by the resistive dividing network. FIG. 20 shows the temperature characteristic of the voltage VNN, wherein the horizontal axis represents temperature (C), the vertical axis represents voltage (V), and the temperature coefficient of the voltage VNN is 0.17 mV/° C.

FIG. 21 is a circuit diagram of another example of the first voltage source circuit 2a shown in FIG. 17. In FIG. 21, items that are the same as or similar to those shown in FIG. 19 bear the same reference numbers.

In FIG. 21, the first voltage source circuit 2a includes the n-channel type field effect transistors M31 and M32, p-channel type field effect transistors M35 through M37, a constant current source 31, and the resistors R41 and R42.

The field effect transistors M31 and M32 are made of the same substrate and have the same channel dope impurity concentration; they are formed in a p-well of an n-type substrate, and are connected such that the substrate voltage is equal to the source voltage. The field effect transistor M31 has a high concentration n-type gate, and the field effect transistor M32 has a low concentration n-type gate.

By designing so that the transistor size W/L of the field effect transistors M31 and M32 may become equal, the field effect transistors M31 and M32 serve as a field effect transistor pair. The field effect transistor pair M31 and M32 constitute the input transistor of the differential amplifier. The p-channel type field effect transistors M35 and M36 form the current mirror circuit. The output voltage VNN of the differential amplifier is put to the feedback loop formed with the p-channel type field effect transistors M37. Further, the voltage VTEMP can be adjusted as desired by adjusting the resistive divider constituted by the resistors R41 and R42.

The field effect transistor pair M31 and M32 serve as the input transistor of the differential amplifier, and the differential amplifier has an input offset of the voltage VNN that has the positive temperature coefficient. Further, the voltage VTEMP is equal to {(r41+r42)/r42}×VNN, and has a positive temperature coefficient that is obtained by amplifying the voltage VNN by the resistive dividing network.

Here, the temperature coefficient of the voltage VNN can be changed, as in the case of the voltage VPN, by changing the ratio of the channel lengths of the field effect transistors M31 and M32 that have polysilicon gates with the same conductive type polarity. By changing the ratio of the channel lengths L of the field effect transistors M31 and M32, a greater temperature coefficient is obtained; accordingly, output precision of the temperature detecting circuit can be improved.

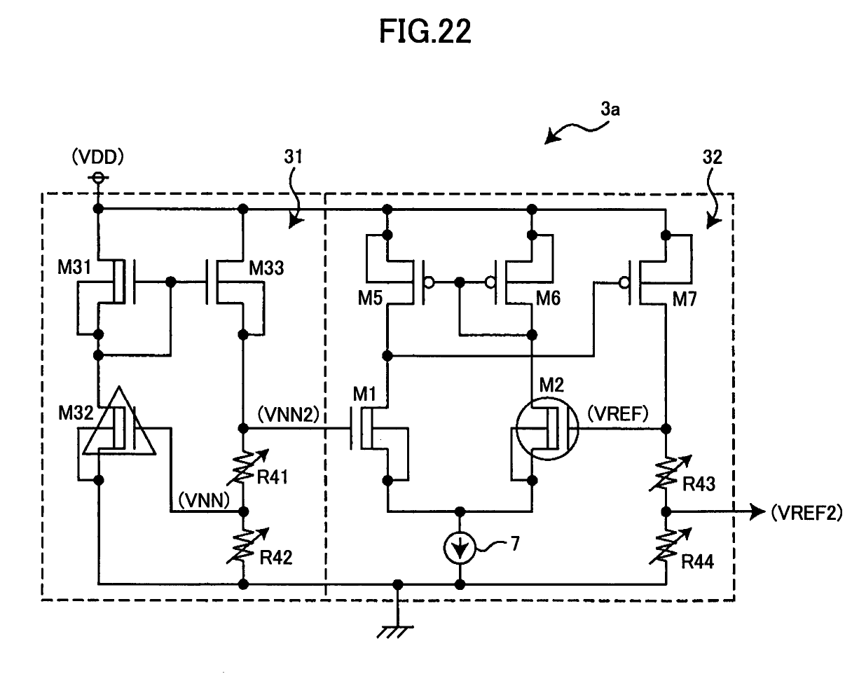

Next, FIG. 22 is a circuit diagram of an example of the second voltage source circuit 3a shown in FIG. 17. In the case of FIG. 22, the configuration of the first voltage source circuit 2a is included in the configuration of the second voltage source circuit 3a. In FIG. 22, the circuit 2a of FIG. 19 is used as a VNN2 generating circuit 31. FIG. 22 shows the case wherein the reference voltage VREF2 is generated by the same circuit as shown in FIG. 12 using the voltage VNN generated by the VNN2 generating circuit 31. In FIG. 22, items that are the same as or similar to shown in FIG. 12 and FIG. 19 bear the same reference numbers.

In FIG. 22, the second voltage source circuit 3a includes the VNN2 generating circuit 31 that is constituted by the first voltage source circuit 2a for generating a voltage VNN2 proportional to the voltage VNN that has a positive temperature coefficient, and a VREF2 generating circuit 32 for generating a reference voltage VREF2 using the voltage VNN2. In addition, the VNN2 generating circuit 31 serves as the first voltage generating unit, and the VREF2 generating circuit 32 serves as the reference voltage generating unit.

The VNN2 generating circuit 31 includes the n-channel type field effect transistors M31 through M33 and the resistors R41 and R42, wherein the field effect transistors M31 and M32 are depletion type transistors and the field effect transistor M33 is an enhancement type transistor. The VNN2 generating circuit 31 is the same as FIG. 19, except that the voltage at the connection section of the field effect transistor M33 and the resistor R41 is called VNN2; accordingly, the explanation is not repeated.

The VREF2 generating circuit 32 includes the n-channel type field effect transistors M1 and M2, the p-channel type field effect transistors M5 through M7, the constant current source 7, and resistors R43 and R44. In the case of FIG. 22, the resistors R41 and R42 serve as the first voltage adjustment circuit, and the resistors R43 and R44 serve as the second voltage adjustment circuit.

The field effect transistors M1 and M2 are made of the same substrate and have the same channel dope impurity concentration; they are formed in a p-well of an n-type substrate, and are connected such that the substrate voltage is equal to the source voltage. The field effect transistor M1 has a high concentration n-type gate, and the field effect transistor M2 has a high concentration p-type gate. The field effect transistor pair M1 and M2 constitute the input transistor of the differential amplifier, the p-channel type field effect transistors M5 and M6 constitute the current mirror circuit, and a feedback loop to the differential amplifier is constituted through the p-channel type field effect transistor M7. The reference voltage VREF2 is set to a desired voltage by changing the resistances of the resistors R43 and R44.

With the structure as described above, since the same current flows to the field effect transistor pair M31 and M32 that constitute the VNN2 generating circuit 31 for generating the voltage VNN2 having the positive temperature coefficient, the voltage between the gate and the source of the field effect transistor M32 serves as the voltage VNN that is the difference of threshold voltages of the field effect transistors M31 and M32, and serves as a signal having a positive temperature coefficient resulting from the difference in the temperature characteristics of the field effect transistors M31 and M32. Further, where r41 represents the resistance of the resistor R41 and r42 represents the resistance of the resistor R42, the voltage VNN2 is expressed by (r41+r42)/r42xVNN, VNN2 having a positive temperature coefficient amplified by the resistor R41.

On the other hand, since the VREF2 generating circuit 32 uses the field effect transistor pair M1 and M2 constituting an input transistor of the differential amplifier, and a current mirror circuit is constituted by the field effect transistors M5 and M6, the same current flows to the field effect transistor pair M1 and M2, and the differential amplifier has the input offset of the voltage VPN having a negative temperature coefficient. Therefore, the voltage VNN2 is provided to the gate of the field effect transistor M1, and the gate voltage of the field effect transistor M2 serves as the reference voltage VREF that is equal to {(r41+r42)/r42×VNN}+VPN by the feedback loop of the field effect transistor M7 and the differential amplifier having the offset of the voltage VPN. As for the reference voltage VREF, temperature coefficients of the voltages VNN and VPN are selected such that they may be offset. Further, a desired reference voltage VREF2 can be obtained by adjusting the resistor ratio of (r44/(r43+r44)), wherein r43 represents the resistance of the resistor R43, and r4 represents the resistance of the resistor R44.

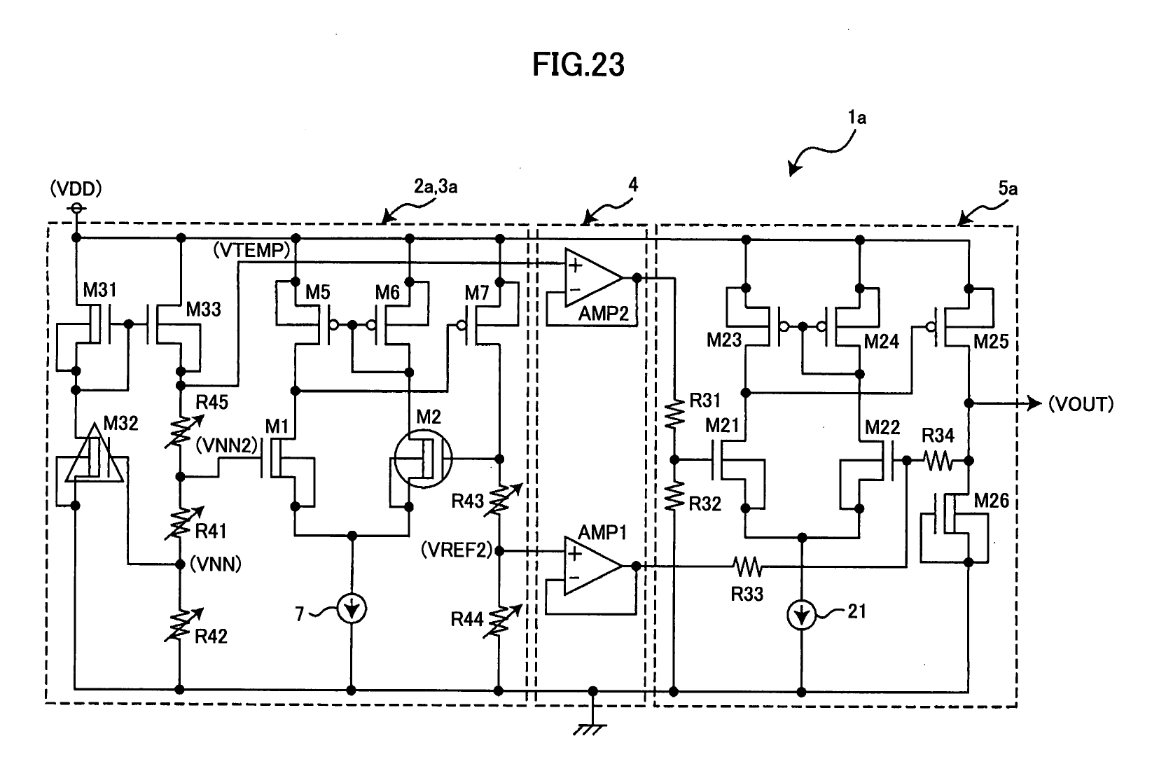

Next, FIG. 23 is a circuit diagram showing a specific example of the temperature detecting circuit 1a, outline of which is shown in FIG. 17. The example in FIG. 23 includes the circuit as shown in FIG. 22 serving as the first voltage source circuit 2a and the second voltage source circuit 3a, except that a resistor R45 is added between the source of the field effect transistor M33 and the resistor R41 in order to obtain the voltage VTEMP that is greater than the voltage VNN2 based on the voltage VNN.

Since the first voltage source circuit 2a and the second voltage source circuit 3a in FIG. 23 are the same as those shown in FIG. 22, the descriptions thereof are not repeated. In addition, the circuit of FIG. 19 may be used as the first voltage source circuit 2a, and the circuit of FIGS. 6 through 8, FIGS. 10 through 12, and FIG. 14 may be used as the second voltage source circuit 3a. However, when the circuit of FIG. 10 is used as the second voltage source circuit 3a, the operation amplifier AMP1 of the impedance conversion circuit 4 is omitted, and the reference voltage VREF2 is directly provided to the resistor R33.

The subtracter circuit 5a is the same as the subtracter circuit 5 shown in FIG. 15, except that resistors R31 through R34 replace the resistors R1 through R4, respectively. The subtracter circuit 5a is configured such that: the operation amplifier AMP2 converts the impedance of the voltage VTEMP, which voltage is then divided by the resistors R31 and R32, and the divided voltage is provided to the non-inverting input terminal of the operation amplifier AMP; the operation amplifier AMP1 converts the impedance of the reference voltage VREF2, which voltage is provided to the inverting input terminal of the operation amplifier AMP through the resistor R33; and the output voltage VOUT of the operation amplifier AMP is fed back to the inverting input terminal of AMP through the resistor R34.

With the structure as described above, the properties of the voltages shown in FIG. 23 over temperature change become as shown in FIG. 18. Since the voltage VNN has the positive temperature characteristic, the voltage VTEMP generated by amplifying the voltage VNN by a factor of m rises with a temperature rise. On the other hand, since the temperature coefficient of the reference voltage VREF2 is zero, VREF2 is temperature insensitive, and stays at a fixed voltage. The output voltage VOUT is obtained by subtracting the reference voltage VREF2 from the voltage VTEMP, and multiplied by a resistor ratio n, that is, VOUT is expressed by the following formula (5).

$$\begin{matrix}VOUT = n \times ( m \times VNN - VREF 2 ) \\ = n \times ( VTEMP - VREF 2 )\end{matrix} \\ where \\ m = ( r 41 + r 42 + r 45 ) / r 42 and \\ n = r 32 / r 31 = r 34 / r 33 , \qquad ( 5 )$$

where r41, r42, and r45 are resistances of the resistors R41, R42, and R45, respectively, and

r31 through r34 represent resistances of the resistors R31 through R34, respectively, under a condition that r31=r33 and r32=r34.

Here, the low voltage operation of the temperature detecting circuit 1a of FIG. 23 is specifically explained using numeric values.

As described above, since the temperature coefficient of the voltage VNN is small at about 0.17 mV/° C., it desired to raise the temperature sensitivity of the temperature detecting circuit 1a. The voltage VNN approximately ranges between 0.04 V and 0.07 V over a temperature range between 0 and 100° C. If a temperature coefficient of, e.g., about 5 mV/° C. is desired, the voltage VNN has to be amplified by a factor of about 30. On the other hand, there is a requirement for the low voltage operation. Accordingly, a difference between the reference voltage VREF2 and the voltage VTEMP is obtained, and the difference is amplified, as shown in the formula (5).

Here, the minimum operating voltage Vmin of the temperature detecting circuit 1a of FIG. 23 at the time of m=6 and n=5 is considered.

The minimum operating voltage Vmin of the temperature detecting circuit 1a of FIG. 23 is a sum of the voltage VdsM31 between the drain and the source of the field effect transistor M31, the voltage VgsM33 between the gate and the source of the field effect transistor M33, and the voltage VTEMP, which is expressed by the following formula (6).

$$\begin{matrix}Vmin = VdsM 31 + VgsM 3 \; 3 + VTEMP \\ = ( VgsM 3 \; 1 - VthM 3 \; 1 ) + VgsM 3 \; 3 + VTEMP \\ = - VthM 3 \; 1 + VgsM 33 + VTEMP\end{matrix} \qquad ( 6 )$$

Here, VthM31 is the threshold voltage of the field effect transistor M31, and VgsM31 is the voltage between the gate and the source of the field effect transistor M31.

Here, the voltage VgsM31 between the gate and the source of the field effect transistor M31 is 0, given that the gate and the source are connected. In the case that the threshold voltage of the field effect transistors M31 and M32 is −0.4 V, the threshold voltage of the field effect transistor M33 is 0.3 V, and the voltage VTEMP is about 0.3 V (=6×0.05 V), the minimum operating voltage Vmin becomes as expressed by the following formula (7).

$$\begin{matrix}Vmin = - VthM 31 + VgsM 33 + VTEMP \\ = - ( - 0.4 ) + VgsM 33 + 0.3 \\ = 0.7 V + VgsM 33\end{matrix} \qquad ( 7 )$$

Therefore, the minimum operating voltage Vmin is determined by the voltage VgsM33 between the gate and the source of the field effect transistor M33. For example, when the voltage VgsM33 between the gate and the source is 0.3 V, the circuit can be operated at the low voltage that is about 1 V. In this case, since the current consumption of the temperature detecting circuit 1 is about 3 μA, power consumption is about 3 μA×1V=3 μW. Accordingly, the temperature detecting circuit according to the second embodiment realizes the low voltage operation and low power operation.

Further, although the example described above is in the case where the impedance conversion circuit 4 is used, if the impedance conversion is not required, the impedance conversion circuit 4 may be dispensed with. In this case, the voltage VTEMP from the first voltage source circuit 2a is directly provided to the resistor R31, and the reference voltage VREF2 from the second voltage source circuit 3a is directly provided to the resistor R33.

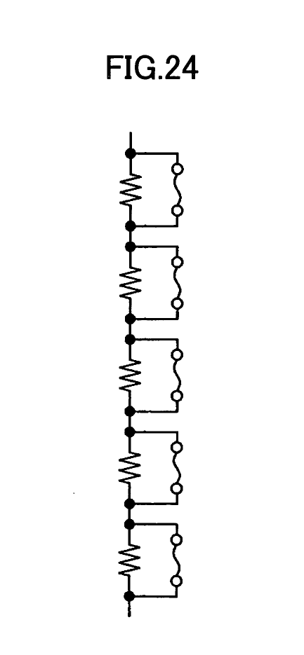

In addition, the resistance of the resistors shown as variable resistors in the first and the second embodiments may be fixed at the time of manufacturing, or alternatively, may be implemented by two or more resistors connected in series, a fuse being connected in parallel with each of the resistors as shown in FIG. 24, wherein the resistance is adjusted by disconnecting a selected fuse by laser trimming after manufacture. Further, the temperature detecting circuit according to the first and the second embodiments may be made integrated into an IC.

In the first and the second embodiments, the voltage VPN serves as the voltage that has a positive temperature coefficient, the voltage VPN being obtained from the work function difference of two field effect transistors that have gate electrodes of the same conductive type, but different concentration of impurities; and the voltage VNN serves as the voltage that has a negative temperature coefficient, the voltage VNN being obtained from the work function difference of two field effect transistors that have gate electrodes of different conductive types. For example, the voltage VPN can be expressed by secondary regression such as the following formula (8), wherein T represents surrounding temperature.
VPN=−4.6×10⁻⁷×T²−4.9×10⁻⁴×T+1.0 (8)

The primary coefficient of the formula (8) expresses an inclination of the voltage VPN to temperature change, and the temperature sensitivity (temperature coefficient) is −0.49 mV/° C., which is a small value to serve as a temperature coefficient of a practical temperature detecting circuit. Generally, for improving the output precision, which is the important property of a temperature detecting circuit, it is desirable to enlarge a voltage corresponding to temperature change of 1° C. (that is, temperature coefficient) such that the temperature sensitivity be high. If, for example, the temperature coefficient of the voltage VPN is desired to be about 5 mV/° C., what is necessary is to set the ratio of dividing resistances so that the amplification factor of about 10 can be obtained.

However, since the value of the secondary coefficient of the formula (8) is also amplified, the secondary coefficient expressing the non-linearity that is one of the measures of output precision of the temperature detecting circuit, it is desired to make the amplification factor as small as possible. Therefore, it is necessary to enlarge the temperature coefficient at the source before amplifying, and decrease the amplification factor. This can be realized by adjusting the size ratio of the channel lengths L of the two field effect transistors. The same applies to the voltage VNN.

Further, although the first and the second embodiments are described about the case where the work function difference of the gate electrodes of the n-channel type field effect transistor is used by the first and the second voltage source circuits, this is only an example. That is, the present invention is not limited to this, but the first and the second voltage source circuits may use a work function difference of gate electrodes of p-channel type field effect transistors.

Further, the present invention is not limited to these embodiments, but variations and modifications may be made without departing from the scope of the present invention.

The present application is based on Japanese Priority Application No. 2005-062433 filed on Mar. 7, 2005 with the Japanese Patent Office, the entire contents of which are hereby incorporated by reference.

What is claimed is:

1. A temperature detecting circuit, comprising:
a first voltage source circuit for generating a first voltage that has a temperature coefficient using a work function difference of gate electrodes of two field effect transistors;
a second voltage source circuit for generating a predetermined reference voltage independent of temperature change using a work function difference of gate electrodes of a plurality of field effect transistors; and
a subtracter circuit for obtaining a difference voltage by subtracting the first voltage from the reference voltage, and for amplifying the difference voltage.

2. The temperature detecting circuit as claimed in claim 1, wherein
the first voltage source circuit includes a first field effect transistor that has a high concentration n-type gate, and a second field effect transistor that has a high concentration p-type gate for generating the first voltage that has a negative temperature coefficient using the work function difference of the gate electrodes of the first and the second field effect transistors that have polysilicon gates of different conductive type polarities.

3. The temperature detecting circuit as claimed in claim 1, wherein
the first voltage source circuit includes a first field effect transistor that has a high concentration n-type gate, and a second field effect transistor that has a low concentration n-type gate for generating the first voltage that has a positive temperature coefficient using the work function difference of gate electrodes of the first and the second field effect transistors that have polysilicon gates of the same conductive polarity.

4. The temperature detecting circuit as claimed in claim 2, wherein
channel lengths of the first and the second field effect transistors are different.

5. The temperature detecting circuit as claimed in claim 2, wherein
the second voltage source circuit includes a third field effect transistor that has a high concentration n-type gate, and a fourth field effect transistor that has a high concentration p-type gate for generating the reference voltage that is independent of temperature change using the work function difference of gate electrodes of the third and the fourth field effect transistors that have polysilicon gates of different conductive polarities.

6. The temperature detecting circuit as claimed in claim 5, wherein
channel lengths of the third and the fourth field effect transistors are different.

7. The temperature detecting circuits as claimed in claim 6, wherein
a ratio of channel lengths of the third and the fourth field effect transistors is selected so that the reference voltage may not vary with temperature change.

8. The temperature detecting circuit as claimed in claim 1, wherein the second voltage source circuit includes
a first voltage generating unit that includes a first field effect transistor that has a high concentration n-type gate, and a second field effect transistor that has a low concentration n-type gate for generating a first voltage that has a positive temperature coefficient using the work function difference of gate electrodes of the first and the second field effect transistors that have a polysilicon gate of the same conductive polarity, and
a reference voltage generating unit that includes a third field effect transistor that has a high concentration n-type gate, and a fourth field effect transistor that has a high concentration p-type gate for generating a second voltage that has a negative temperature coefficient using the work function difference of gate electrodes of the third and the fourth field effect transistors that have polysilicon gates of different conductive polarities, and for generating the reference voltage independent of temperature change by adjusting inclination of the temperature coefficients of the first voltage and the second voltage such that the temperature coefficients may offset each other.

9. The temperature detecting circuit as claimed in claim 8, wherein
the first voltage generating unit is the first voltage source circuit.

10. The temperature detecting circuit as claimed in claim 1, further comprising:
an impedance conversion circuit for converting impedance of the first voltage and the reference voltage that are generated by the first and the second voltage source circuits, respectively, and for outputting the impedance converted voltages to the subtracter circuit.

11. The temperature detecting circuit as claimed in claim 3, wherein
the first voltage source circuit includes a voltage adjustment circuit for voltage adjustment by one of stepping up and stepping down the voltage of the first voltage.

12. The temperature detecting circuit as claimed in claim 5, wherein
the second voltage source circuit includes a voltage adjustment circuit for voltage adjustment by one of stepping up and stepping down the reference voltage.

13. The temperature detecting circuit as claimed in claim 8, wherein
the first voltage generating unit includes a first voltage adjustment circuit for voltage adjustment by one of stepping up and stepping down the first voltage, and
the reference voltage generating unit includes a second voltage adjustment circuit for voltage adjustment by one of stepping up and stepping down the reference voltage.

14. The temperature detecting circuit as claimed in claim 11, wherein
the voltage adjustment circuit includes a plurality of resistors for performing voltage adjustment by trimming and varying resistance.

15. The temperature detecting circuit as claimed in claim 13, wherein
each of the first and each the second voltage adjustment circuits includes a plurality of resistors for performing voltage adjustment by trimming and varying resistance.

16. The temperature detecting circuit as claimed in claim 1 wherein
the first voltage source circuit, the second voltage source circuit, and the subtracter circuit are integrated into an IC.
